(19) United States
(12) Patent Application Publication
(10) Pub. No.: US 2006/0162957 A1
(43) Pub. Date: Jul. 27, 2006

(54) Printed circuit board, printed circuit module and method for producing a printed circuit board

(76) Inventors: Jorg Kindermann, Munchen (DE); Simon Albert, Bad Homburg (DE)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/041,536

(22) Filed: Jan. 24, 2005

(51) Int. Cl. H05K 1/11; H05K 1/18

(52) U.S. Cl. 174/255; 174/260

(57) ABSTRACT

One embodiment of the present invention relates to a printed circuit board comprising one inner metal layer sandwiched between a first and a second insulating layers, wherein the inner metal layer is structured to comprise a conductive path and a bond pad, wherein the first insulating layer includes a recess for receiving an integrated device, wherein the bond pad of the inner metal layer is located in the recess.

### BACKGROUND OF THE INVENTION

1. Field of the Invention

The present invention is related to printed circuit boards, in particular to multi-layer printed circuit boards. The present invention is further related to a method for producing such a printed circuit board and a printed circuit module comprising a printed circuit board and an integrated device attached thereon.

2. Description of the Related Art

Since the propagation of electromagnetic signals on signal lines depends on the dielectric environment of the respective signal line, the signal propagation on signal lines of outer metal layers of a printed circuit board (PCB) is usually faster than the signal propagation of the signal lines of inner metal layers of the printed circuit board. In printed circuit boards and modules designed for high-frequency signalling, the propagation delay, i.e. skew, of a plurality of signals (e.g., in bus systems) has to be substantially small. To achieve this, the length of the signal lines on the outer metal layers has to be designed longer than the signal lines in the inner metal to equalize the propagation delays on different signal lines. This consumes more space (with constant size of a printed circuit board) and decreases the available area for integrated devices to be attached on the printed circuit board. Furthermore, the electrical characteristics, such as the signal integrity of the printed circuit board, degrade due to an increasing crosstalk of neighboured signal lines.

As in conventional printed circuit modules in which the outer metal layer provides the contact pads for electrically contacting the integrated devices to be attached thereon, a shift of the signal lines to inner metal layers would substantially increase the number of the required vias in close proximity to the integrated devices and thus increase the number of required metal layers for contacting all device pins or require costly technologies such as the provision of blind or buried vias.

Therefore, there is a need to provide a printed circuit board with improved electrical properties and with a reduced number of conductive vias. Furthermore, there is a need to provide a printed circuit module with improved electrical properties.

### SUMMARY OF THE INVENTION

According to a first aspect of the present invention, a printed circuit board is provided comprising one inner metal layer sandwiched between a first insulating layer and a second insulating layer, wherein the inner metal layer is structured to comprise a conductive path and a bond pad and wherein the first insulating layer includes a recess for receiving an integrated device. The bond pad of the inner metal layer is located in the recess.

In one embodiment, the printed circuit board comprises a recess which is formed within the first insulating layer so that the bond pad of the inner metal layer is revealed and can be contacted by respective contacting solder balls of an electronic device. The signal paths are completely located within the inner metal layer so that no signal path has to be provided on an outer metal layer of the printed circuit board. Thus, the skew of a plurality of synchronized signals, e.g., in a bus system, may be decreased just by maintaining identical signal path length as each signal path has the same dielectric environment.

According to a further embodiment of the present invention, at least one outer surface of the printed circuit board carries an outer metal layer. The outer metal layer may be arranged to substantially cover the surface of at least one of the first and the second insolating layers to provide shielding. Furthermore, a connection port to be connected by a supply voltage may be provided on the outer metal layer.

A plurality of inner metal layers in the printed circuit board may be provided, each separated by interposing insulating layers, wherein each inner metal layer comprises a conductive path wherein at least one interconnection via between two inner metal layers is provided.

According to another aspect of the present invention, a printed circuit board is provided comprising a plurality of printed circuit board elements (PCB elements), each PCB element including an insulating layer having metal layers on both sides, wherein the PCB elements are sandwiched by means of a further insulating layer to form the printed circuit board. At least one of the metal layers is structured to comprise a conductive path and a bond pad wherein the structured metal layer is an inner metal layer of the printed circuit board formed by the PCB elements. A recess is provided in at least one of the outer PCB elements of the printed circuit board which uncovers the bond pad of the structured inner metal layer.

According to another aspect of the present invention, a method for producing a printed circuit board is provided. The method comprises providing two insulating layers, providing a metal layer in between the two insulating layers, wherein the metal layer is structured to comprise a conductive path and a bond pad, and structuring at least one of the insulating layers to include a recess in the insulating layer so that the bond pad is uncovered wherein the recess is formed to receive an electronic device.

The method may be adapted to produce a printed circuit board wherein the conductive paths are led in an inner metal layer so that the dielectric environment of all conductive paths is similar. This reduces the skew of different signals on different signal paths in the printed circuit board (provided that the signal paths all have the same lengths).

According to a further embodiment of the present invention, at least one of the insolating layers is covered with an outer metal layer as a shielding.

According to a further aspect of the present invention, a method for producing a printed circuit board is provided comprising providing a first printed circuit board element and a second printed circuit board element, each comprising two metal layers arranged on both sides of an insulating layer, structuring at least one of the metal layers of at least one of the first and second PCB elements to comprise a conductive path and a bond pad, binding the two PCB elements by interposing a further insulating layer such that the structured metal layer is in contact with the interposed further insulation layer, and structuring at least one of the outer surfaces of the bonded PCB elements to include a recess in the insulating layer so that the bond pad of the structured metal layer is revealed.

According to another aspect of the present invention, a printed circuit module is provided comprising a printed circuit board having a recess in an insulating layer so that a bond pad of an inner metal layer is revealed and an integrated device having a bond port to provide an electrical connection to an electronic device, wherein the electronic device is introduced into the recess of the printed circuit board and wherein the bond port is electrically connected to the bond pad of the printed circuit board.

### BRIEF DESCRIPTION OF THE DRAWINGS

Preferred embodiments of the present invention are further explained in more detail with reference to the accompanying drawings, in which:

FIG. 1 is a cross-sectional view of a part of a printed circuit board according to one embodiment of the present invention; and

FIG. 2 is a perspective view of a printed circuit board according to one embodiment of the present invention.

### DETAILED DESCRIPTION OF THE PREFERRED EMBODIMENT

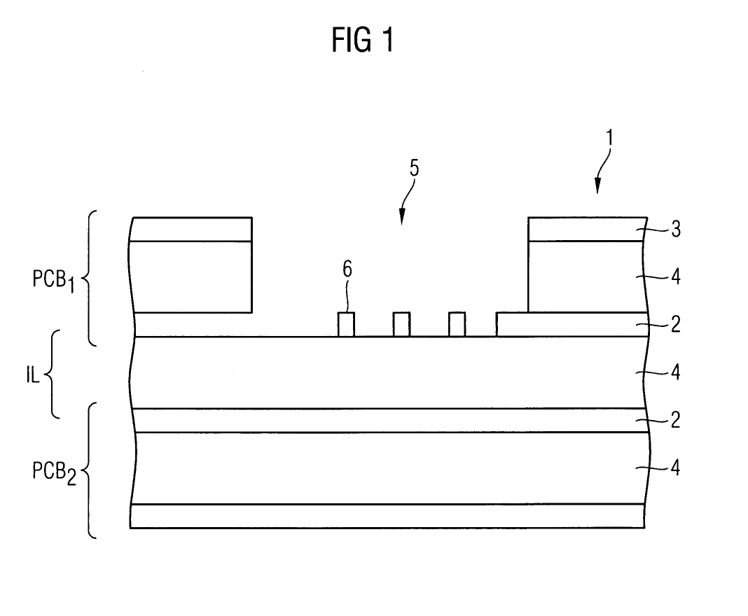

In FIG. 1, a multi-layer printed circuit board 1 is depicted. As shown, the multi-layer printed circuit board 1 comprises two inner metal layers 2 and two outer metal layers 3 disposed on respective outer surfaces of the printed circuit board 1. Each of the inner and outer metal layers 2, 3 is separated from the other by an insulation layer 4. The insulation layer 4 comprises a material usually used for producing printed circuit boards, such as a resin and the like, providing good dielectric characteristics such as a high resistance.

In prior art printed circuit boards, the outer metal layers are usually structured to provide conductive paths and/or bond pads to be connected with integrated or non-integrated electronic devices attached on the printed circuit board.

Such a multi-layer printed circuit board 1 can be manufactured by different methods. According to one method, a number of printed circuit board elements (PCB elements) PCB₁, PCB₂ are manufactured separately which are joined by means of a further insulation layer arranged in between two PCB elements. The PCB element PCB₁, PCB₂ can be fixedly joined by laminating, adhering and/or other similar techniques to produce a single body printed circuit board 1.

As shown in FIG. 1, a first PCB element PCB₁ is formed by the upper two metal layers and the insulating layer 4 arranged in between and is indicated by the reference PCB₁. A second PCB element PCB₂ is formed by the lower two metal layers and the insulating layer arranged in between and is indicated by the reference PCB₂. A further insulating layer arranged between the first PCB element PCB₁ and the second PCB element PCB₂ is indicated by the reference IL.

As another method for producing such a multi-layer printed circuit board, PCB elements, each comprising a metal layer sandwiched between a first insulating layer and a second insulating layer, are arranged on both surfaces of the intermediate metal layer. By combining a plurality of such PCB elements, a printed circuit board may be formed. It may be useful to arrange a further metal layer between two neighboured PCB elements, but not necessarily.

The printed circuit board 1 of FIG. 1 has a recess 5, substantially the size of an electronic device, reaching from one outer surface of the printed circuit board 1 to one of the inner metal layers 2. The inner metal layers 2 are structured and normally comprise conductive paths and, at least in the area of the recess, bond pads 6 to be connected by means of a bonding process with an electronic device. According to one embodiment, as shown in FIG. 1, the outer surface of the printed circuit board 1 is covered by the outer metal layer 3. The outer metal layer 3 may be structured to not provide a shielding for electromagnetic radiation. A connection element is provided on the outer surface of the printed circuit board 1 to connect the outer metal layer 3, for example, to a pre-determined potential.

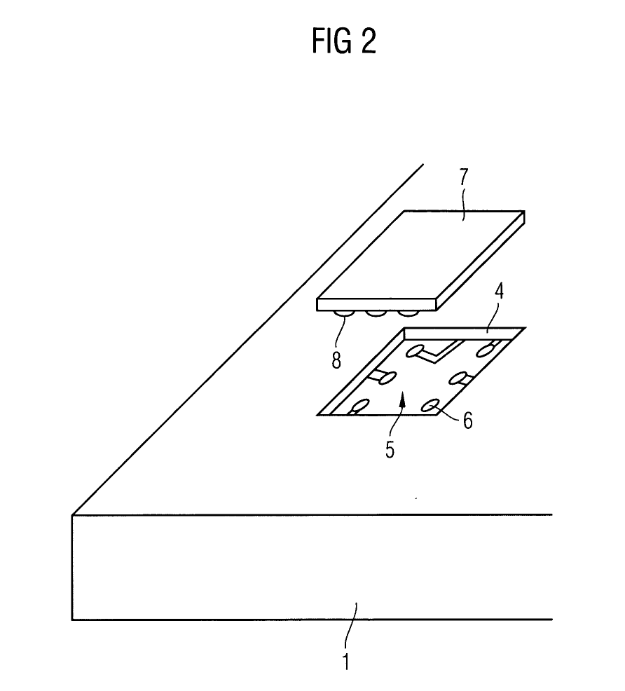

In FIG. 2, a perspective view of the multi-layer printed circuit board 1 is shown. Furthermore, the recess 5 is depicted in a size of an integrated circuit packaged as a Ball Grid Array 7 (BGA) having solder balls 8 on its lower side. The integrated circuit may be received in the recess 5. The recess 5 may be at least the size of the package of the integrated circuit, and the bond pad 6 structured in the inner metal layer 2 revealed by the recess 5 is interconnected with respective conductive paths and/or respective vias to other inner metal layers 2 and arranged so that the solder balls 8 of the integrated circuit package are facing the bond pads 6 provided in the correct orientation of the Ball Grid Array.

Thereby, all signalling paths to and from the electronic integrated device are located inside of the printed circuit board 1 and formed from the structured inner metal layer 2. In the case of a plurality of signal lines, the signal propagation on the signalling paths may be substantially constant so that the skew between different signals, e.g., in a bus system, may be minimized by providing that the bus lines all have the same length. The propagation delay of the signal path in the inner metal layers 2 is substantially constant per length since the dielectric environment of the signal paths is substantially constant. Between two inner metal layers 2, as well as between one outer metal layer 3 and one inner metal layer 2, conductive vias may be provided to connect signal paths on different metal layers. In the latter case, the outer metal layers 3 may be utilized as voltage supply planes, such as a ground plane or a supply voltage VDD plane.

The forming of the recess 5 may be performed in the manufacturing process of the bonded circuit boards as the insulating layer between the outer metal layer 3 and the inner metal layer 2 are produced by using an insolating foil, e.g., a prepreg foil on which the metal layers are pressed to fix the metal layers on the surface of the insulation layer. Before pressing the metal layers, the prepreg foil may be formed, e.g., in a die cutting process, to insert the recesses for the electronic devices to be attached to the printed circuit board.

By means of the preformed recesses 5 for placing the electronic devices, the accuracy of positioning the electronic devices may be further increased, thereby increasing the yield of manufacturing of printed circuit board modules.

While the foregoing is directed to embodiments of the present invention, other and further embodiments of the invention may be devised without departing from the basic scope thereof, and the scope thereof is determined by the claims that follow.

What is claimed is:

1. An apparatus, comprising:
a printed circuit board comprising an inner metal layer disposed between a first insulating layer and a second insulating layer, wherein the inner metal layer is structured to comprise a conductive path and a bond pad, wherein the first insulating layer includes a recess for receiving an electronic device, and wherein the bond pad of the inner metal layer is located in the recess.

2. The apparatus of claim 1, further comprising:
an outer metal layer disposed on at least one outer surface the printed circuit board.

3. The apparatus of claim 2, wherein the outer metal layer includes a connection port connectable to a supply voltage.

4. The apparatus of claim 2, wherein the outer metal layer is arranged to substantially cover a surface of at least one of the first and second insulating layers to provide shielding.

5. The apparatus of claim 1, wherein a plurality of inner metal layers are provided, each separated by interposing insulating layers, wherein each of the inner metal layers comprises a respective conductive path.

6. The apparatus of claim 5, further comprising:
at least one interconnection via disposed between two neighboured inner metal layers.

7. The apparatus of claim 1, further comprising:
the electronic device having a bond port providing an electrical connection to the electronic device, wherein the electronic device is coupled into the recess of the printed circuit board, wherein the bond port is electrically connected to the bond pad of the printed circuit board, and wherein the printed circuit board and the electronic device together form a printed circuit module.

8. The apparatus of claim 7, further comprising:
an outer metal layer disposed on at least one outer surface the printed circuit board, wherein the outer metal layer includes a connection port connectable to a supply voltage.

9. The apparatus of claim 7, wherein a plurality of inner metal layers are provided, each separated by interposing insulating layers, wherein each of the inner metal layers comprises a respective conductive path, and further comprising at least one interconnection via disposed between two neighboured inner metal layers.

10. An apparatus, comprising:
a printed circuit board comprising:
a plurality of PCB elements, each PCB element including an insulating layer having a respective metal layer disposed on both sides of the insulating layer; and
a further insulating layer sandwiched between respective adjacent PCB elements;
wherein at least one of the metal layers is a structured metal layer comprising a conductive path and a bond pad, the structured metal layer disposed as an inner metal layer of the printed circuit board, and
wherein a recess is provided in an outer metal layer of at least one PCB element of the printed circuit board, the recess providing an opening to the bond pad of the structured inner metal layer.

11. The apparatus of claim 10, wherein the outer metal layer includes a connection port connectable to a supply voltage.

12. The apparatus of claim 10, wherein at least one outer metal layer is arranged to substantially cover a surface of the respective insulating layer of the respective PCB element to provide shielding.

13. The apparatus of claim 10, wherein a plurality of inner metal layers are provided, each separated by interposing insulating layers, wherein each of the inner metal layers comprises a respective conductive path.

14. The apparatus of claim 13, further comprising:
at least one interconnection via disposed between two neighboured inner metal layers.

15. The apparatus of claim 10, further comprising:
an electronic device having a bond port providing an electrical connection to the electronic device, wherein the electronic device is coupled into the recess of the printed circuit board, wherein the bond port is electrically connected to the bond pad of the printed circuit board, and wherein the printed circuit board and the electronic device together form a printed circuit module.

16. A method for producing a printed circuit board, comprising:
providing two insulating layers;
providing a metal layer between the two insulating layers, wherein the metal layer is structured to comprise a conductive path and a bond pad; and
structuring at least one of the insulating layers to include a recess in the insulating layer for receiving an electronic device, wherein the bond pad is uncovered where the recess is formed.

17. The method of claim 16, further comprising:
covering at least one of the insulating layers with an outer metal layer as a shielding layer.

18. A method for producing a printed circuit board (PCB), comprising:
providing a first PCB element and a second PCB element, each comprising two metal layers arranged respectively on both sides of an insulating layer;
structuring at least one of the metal layers of at least one of the first and second PCB elements to comprise a conductive path and a bond pad;
binding the two PCB elements by interposing a further insulating layer, such that the structured metal layer is in contact with the interposed further insulation layer; and
structuring at least one outer surface of the bonded PCB elements to include a recess through a respective outer metal layer and the respective insulating layer such that the bond pad of the structured metal layer is revealed.

19. The method of claim 18, wherein at least one of the insulating layers is provided with a conductive via to interconnect two neighboured metal layers of the printed circuit board.

20. The method of claim 18, wherein the further insulating layer is provided with a conductive via to interconnect two neighboured metal layers of the printed circuit board.
